(19) United States
(12) Patent Application Publication
(10) Pub. No.: US 2022/0102943 A1
(43) Pub. Date: Mar. 31, 2022

(54) METHOD OF MAKING LASER DIODE WITH HIGHLY REFLECTIVE LAYER

(71) Applicant: INSTITUTE OF NUCLEAR ENERGY RESEARCH, ATOMIC ENERGY COUNCIL, EXECUTIVE YUAN, R.O.C., Taoyuan City (TW)

(72) Inventors: MENG-HSIN CHEN, TAOYUAN CITY (TW); HSUEH-HUI YANG, TAOYUAN CITY (TW); CHUN-LING CHANG, TAOYUAN CITY (TW)

(21) Appl. No.: 17/459,182

(22) Filed: Aug. 27, 2021

(30) Foreign Application Priority Data
Sep. 29, 2020 (TW) 109133858

(51) Int. Cl. H01S 5/40; H01S 5/042; H01S 5/028; H01S 5/024

(52) U.S. Cl. CPC H01S 5/4025; H01S 5/04256; H01S 5/0281; H01S 5/02423; H01S 5/0284

(57) ABSTRACT

A method of fabricating a laser diode with a reflective layer which is applied to an epitaxial structure of the laser diode where initially the laser diode is placed in a coating device. The laser diode is then coated with additional layers of insulation, metal and a protective layer. A rapid thermal annealing process is applied to the layered laser diode. The insulation layer, metal layer and protective layer form a reflective structure on one side of the laser diode.

### FIELD OF THE INVENTION

The present invention relates generally to a fabrication method and the structure thereof, and particularly to a method of making laser diode with highly reflective layer.

### BACKGROUND OF THE INVENTION

The word “LASER” for a laser diode is the acronym of “Light Amplification by Stimulated Emission of Radiation”. A laser diode is also called a semiconductor diode, abbreviated as LD.

Laser diodes can emit coherent rays with identical wavelength and phase. The rays generated by injected currents travel back and forth between two reflective films for amplification until laser resonance occurs. The two films are an antireflection (AR) film and a highly reflective (HR) film.

An antireflection film is also called a transmittance enhancing film. Its main function is to reduce or eliminate reflection from the surfaces of lenses, prisms, or mirrors and thus increasing their transmittance and reducing or eliminating scattering light of the system. It is an optical thin film having the broadest applications and greatest amount of production.

On the other hand, a highly reflective film is used for enabling least loss while reflecting laser or other light sources. It is usually adopted to laser diode applications, for example, folded path for laser beams and end mirrors for laser cavity.

The highly reflective surface of a laser diode is usually formed by alternately stacking multiple layers of dielectric materials with high and low refractivity, which is called the quarter wave stack. The thickness of each layer must be a quarter of the wavelength. In addition, multiple layers are required for the stack to achieve the effect of high reflectivity.

Accordingly, while fabricating highly reflectively films in laser diodes, how to reduce the number of layers and simplify the fabrication for shortening the process time as well as costs have become the major challenge for this field.

### SUMMARY

An objective of the present invention is to provide a laser diode with highly reflective layer and the method for making the same. By using a coating method, a reflective structure can be formed on one side of the laser diode. In addition, since no heating is required for coating, the fabrication time according to the present invention can be shortened. Furthermore, the reflection function can be achieved merely by an insulation layer, a metal layer, and a protection layer.

To achieve the above objective, the present invention provides a method of making a laser diode with highly reflective layer, which comprises steps of: placing a laser diode in a coating device; performing a coating process on the laser diode at the room temperature, and stacking sequentially on one side of the laser diode to form an insulation layer, a metal layer, and a protection layer; withdrawing and performing a rapid thermal annealing process (RTA) on the laser diode with the insulation layer, the metal layer, and the protection layer at a temperature; and using the insulation layer, the metal layer, and the protection layer to form a reflective structure on one side of the laser diode.

According to an embodiment of the present invention, the coating device includes a plating device, an evaporation device, or a sputtering device.

According to an embodiment of the present invention, the operating temperature for the rapid thermal annealing process is between 200° C. and 350° C.

To achieve the above objective, the present invention provides a laser diode with highly reflective layer, which comprises: a first electrode, an n-type semiconductor layer, a light-emitting layer, a p-type semiconductor layer, and a second electrode. The n-type semiconductor layer is disposed on the first electrode. The light-emitting layer is disposed on the n-type semiconductor layer. The p-type semiconductor layer is disposed on the light-emitting layer. The second electrode is disposed on the p-type semiconductor layer. An insulation layer is disposed on the same side of the n-type semiconductor layer, the light-emitting layer, and the p-type semiconductor layer. A metal layer is disposed on one side of the insulation layer. A protection layer is disposed on one side of the metal layer.

According to an embodiment of the present invention, the material of the insulation layer is selected from the group consisting of aluminum oxide, tantalum pentoxide, silicon dioxide, silicon oxide, titanium dioxide, silicon nitride, zinc selenide, magnesium fluoride, silicon, hafnium dioxide, and zirconium dioxide.

According to an embodiment of the present invention, the material of the metal layer is selected from the group consisting of aluminum, copper, silver, and gold.

According to an embodiment of the present invention, the material of the protection layer is selected from the group consisting of aluminum oxide, tantalum pentoxide, silicon dioxide, silicon oxide, titanium dioxide, silicon nitride, zinc selenide, magnesium fluoride, silicon, hafnium dioxide, and zirconium dioxide.

According to an embodiment of the present invention, the thickness of the insulation layer is between 200 Å and 3000 Å.

According to an embodiment of the present invention, the thickness of the protection layer is between 200 Å and 3000 Å.

According to an embodiment of the present invention, the thickness of the metal layer is equal to or greater than 100 Å.

### BRIEF DESCRIPTION OF THE DRAWINGS

FIG. 1 shows a flowchart according to an embodiment of the present invention;

FIG. 2A shows a schematic diagram of the structure according to an embodiment of the present invention;

FIG. 2B shows a schematic diagram of the laser diode according to an embodiment of the present invention; and

FIG. 3 shows a schematic diagram of the experiment on the thickness of the metal layer according to an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The highly reflective surface of a laser diode is usually formed by alternately stacking multiple layers of dielectric materials with high and low refractivity, which is called the quarter wave stack. The thickness of each layer must be a quarter of the wavelength. In addition, multiple layers are required for the stack to achieve the effect of high reflectivity.

The present invention improves a laser diode with highly reflective layer and the method for making the same. By using a coating method, a reflective structure can be formed on one side of the laser diode. In addition, since no heating is required for coating, the fabrication time according to the present invention can be shortened. Furthermore, the reflection function can be achieved by an insulation layer, a metal layer, and a protection layer.

In the following description, various embodiments of the present invention are described using figures for describing the present invention in detail. Nonetheless, the concepts of the present invention can be embodied by various forms. Those embodiments are not used to limit the scope and range of the present invention.

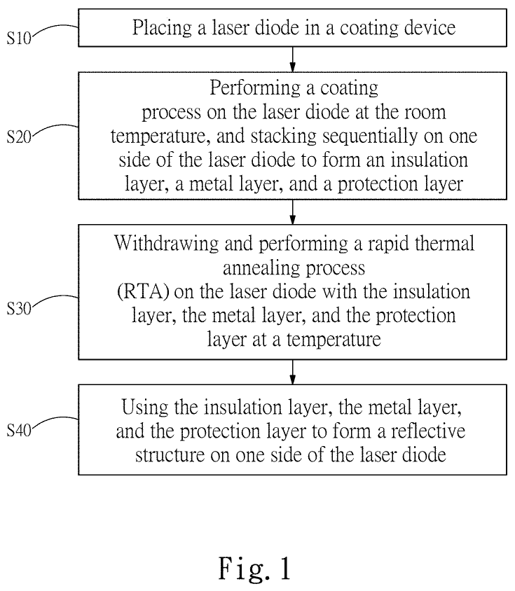

First, please refer to FIG. 1, which shows a flowchart according to an embodiment of the present invention. As shown in the Figure, the method of making a laser diode with highly reflective layer comprises steps of:
Step S10: Placing a laser diode in a coating device;
Step S20: Performing a coating process on the laser diode at the room temperature, and stacking sequentially on one side of the laser diode to form an insulation layer, a metal layer, and a protection layer;
Step S30: Withdrawing and performing a rapid thermal annealing process (RTA) on the laser diode with the insulation layer, the metal layer, and the protection layer at a temperature; and
Step S40: Using the insulation layer, the metal layer, and the protection layer to form a reflective structure on one side of the laser diode.

In the step S10, a laser diode 10 is placed in a coating device (not shown in the Figure). According to the present embodiment, the coating device can be an E-beam evaporator. Nonetheless, any method that can coat the desired material can be adopted. The present invention is not limited to the physical and chemical vapor deposition methods such as plating, evaporation, and sputtering. According to the present embodiment, E-beam evaporation is adopted for description. Nonetheless, the present invention is not limited to the method. After the step S10, the method further comprises a step of:
Step S11: The chamber of the coating device is vacuumed to below 10⁻⁵ torr.

After the laser diode 10 is placed in a chamber (not shown in the Figure) of the coating device, a control device, which is a personal computer, a tablet computer, or a server according to the prior art (not shown in the Figure), connected electrically to the chamber controls the vacuum level of the chamber. Normally, the vacuum level inside the chamber is maintained below 10⁻⁵ torr. The coating device includes a plating device, an evaporation device, and a sputtering device. The physical vapor deposition or the chemical vapor deposition can be adopted for coating.

In the step S20, the costing device is operated at the room temperature (about 25° C. to 30° C.) for coating sequentially on one side (the same side) of a n-type semiconductor layer 13, a light-emitting layer 15, and a p-type semiconductor layer 17 of the laser diode 10 and forming an insulation layer 21, a metal layer 23, and a protection layer 25.

In addition, as shown in the step S30 and the step S40, after the laser diode 10 with the insulation layer 21, the metal layer 23, and the protection layer 25 stacked sequentially on the laser diode 10 withdrawn, a rapid thermal annealing (RTA) process is performed at a temperature of about 200° to 350°. After the RTA process, a reflective structure 20 is formed on one side of the n-type semiconductor layer 13, the light-emitting layer 15, and the p-type semiconductor layer 17.

The advantage of the method of making a laser diode with highly reflective layer is that no heating is required during coating (between the step S10 and the step S20). Thereby, compared with the method according to the prior art, the present invention can save the time of ramping up the temperature before coating and the time for cooling down before withdrawing the laser diode.

The highly reflective surface of the laser diode according to the prior art is formed by multiple pairs of materials with alternate high and low refractivity, which is called the quarter wave stack. To achieve high reflectivity, first, two dielectric materials with large difference in refractivity but matching adherence are selected. A layer of the material with high refractivity and one with low refractivity form a pair. The multiple pairs of materials with alternate high and low refractivity form a highly reflective surface.

Moreover, the electromagnetic theory is adopted to calculate the relation among impedance matching, the refractivity of materials, and the number of pairs of layers. To achieve high reflectivity, the thickness of each layer must precisely be a quarter of the wavelength.

The drawbacks according to the prior art include:
1. Multiple layers: Multiple layers increase process complexity.
2. Accurate thickness: The coating system requires apparatuses for measuring accurate thickness.
3. Complicated design: Computer simulations are required to calculate the high reflectivity achieved by the number of pairs of layers and the coefficients of refraction for different materials.
4. Lower throughout: In the coating process, the temperature should be raised to about 250□, extending the processing time.

The coating process according to the prior art need to heat up to around 250°. After coating, the laser diodes cannot be withdrawn before the temperature is cooled to the room temperature. Thereby, it takes longer time.

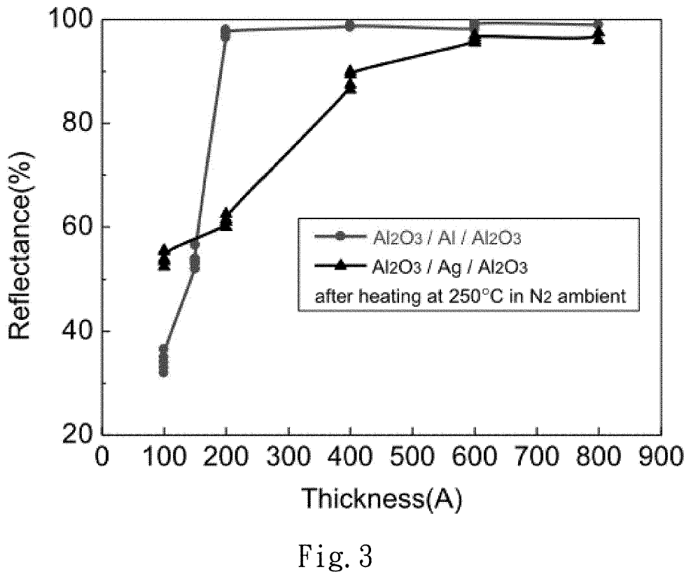

According to the present invention, the thickness of the insulation layer 21 and the protection layer 25 is between 200 Å and 3000 Å. Instead of accurate thickness as required according to the prior art, in which the thickness of each layer must exactly be a quarter of wavelength, the thickness according to the present invention is to meet the requirement for insulation only. According to the present invention, the thickness of the metal layer 23 is equal to or greater than 100 Å. The material of the metal layer 23 is selected from the group consisting of aluminum, copper, silver, and gold. The material of the insulation layer 21 is selected from the group consisting of aluminum oxide, tantalum pentoxide, silicon dioxide, silicon oxide, titanium dioxide, silicon nitride, zinc selenide, magnesium fluoride, silicon, hafnium dioxide, and zirconium dioxide. The material of the protection layer 25 is selected from the group consisting of aluminum oxide, tantalum pentoxide, silicon dioxide, silicon oxide, titanium dioxide, silicon nitride, zinc selenide, magnesium fluoride, silicon, hafnium dioxide, and zirconium dioxide. Please refer to FIG. 3, which shows a schematic diagram of the experiment on the thickness of the metal layer according to an embodiment of the present invention. As shown in the Figure, the x-axis is the thickness of the film in A; the y-axis is the reflectance of film in %. According to the present invention, the tolerance on the thickness of the metal layer 23 is high. Take FIG. 3 for example. When the thickness of aluminum is above 200 Å or the thickness of silver is over 600 Å, high reflectance can be achieved. On the contrary, the thickness according to the prior art must exactly be a quarter of wavelength.

Furthermore, according to the present invention, faster coating, only a 10-minute rapid thermal annealing (RTA) process is required. Then the laser diode with highly reflective layer can be cooled down before withdrawing, meaning that the method according to the present invention is rapid and convenient.

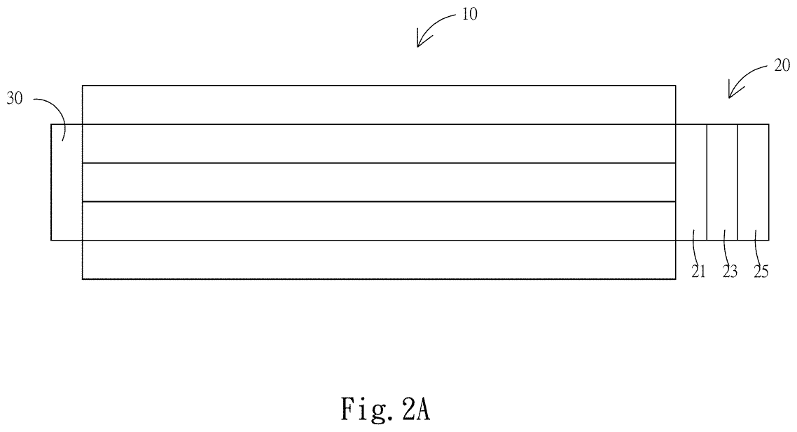

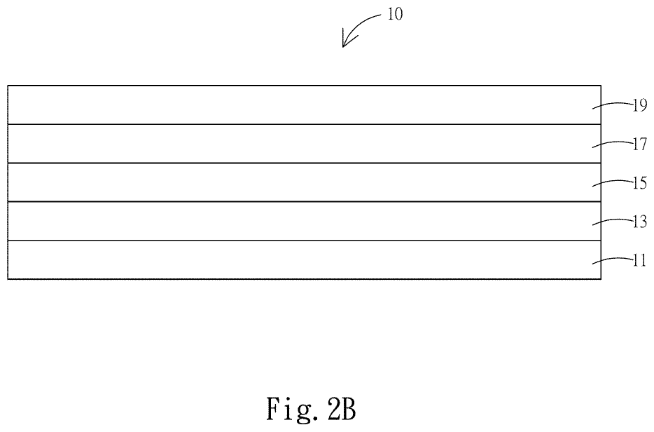

Next, please refer to FIG. 2A, which shows a schematic diagram of the structure according to an embodiment of the present invention, and FIG. 2B, which shows a schematic diagram of the laser diode according to an embodiment of the present invention. As shown in the Figure, the laser diode with highly reflective layer according to the present invention comprises a laser diode 10, a reflective structure 20, and an antireflection structure 30. The laser diode 10 includes a first electrode 11, an n-type semiconductor layer 13, a light-emitting layer 15, a p-type semiconductor layer 17, and a second electrode 19. The n-type semiconductor layer 13 is disposed on the first electrode 11. The light-emitting layer 15 is disposed on the n-type semiconductor layer 13. The p-type semiconductor layer 17 is disposed on the light-emitting layer 15. The second electrode 19 is disposed on the p-type semiconductor layer 17.

An insulation layer 21 of the reflective structure 20 is disposed on one side of the n-type semiconductor layer 13, the light-emitting layer 15, and the p-type semiconductor layer 17. A metal layer 23 is disposed on one side of the insulation layer 21. A protection layer 25 is disposed on one side of the metal layer 23.

According to the embodiment as described above, the present invention improves a laser diode with highly reflective layer and the method for making the same. By using a coating method, a reflective structure can be formed on one side of the laser diode. In addition, since no heating is required for coating, the fabrication time according to the present invention can be shortened. Furthermore, the reflection function can be achieved by an insulation layer, a metal layer, and a protection layer.

What is claimed is:

1. A method of making a laser diode with highly reflective layer, applied to the reflection of the epitaxial structure of said laser diode, comprising steps of:
placing a laser diode in a coating device;
performing a coating process on said laser diode at the room temperature, and stacking sequentially on one side of said laser diode to form an insulation layer, a metal layer, and a protection layer;
withdrawing and performing a rapid thermal annealing process (RTA) on said laser diode with said insulation layer, said metal layer, and said protection layer at a temperature; and
using said insulation layer, said metal layer, and said the protection layer to form a reflective structure on one side of said laser diode.

2. The method of making a laser diode with highly reflective layer of claim 1, wherein said coating device includes a plating device, an evaporation device, or a sputtering device.

3. The method of making a laser diode with highly reflective layer of claim 1, wherein the operating temperature for said rapid thermal annealing process is between 200° and 350°.

4. A laser diode with highly reflective layer, comprising:
a first electrode;
an n-type semiconductor layer, disposed on said first electrode;
a light-emitting layer, disposed on said n-type semiconductor layer;
a p-type semiconductor layer, disposed on said light-emitting layer; and
a second electrode, disposed on said p-type semiconductor layer;
wherein an insulation layer is disposed on one side of said n-type semiconductor layer, said light-emitting layer, and said p-type semiconductor layer; a metal layer is disposed on one side of said insulation layer; and a protection layer is disposed on one side of said metal layer.

5. The laser diode with highly reflective layer of claim 4, wherein the material of said insulation layer is selected from the group consisting of aluminum oxide, tantalum pentoxide, silicon dioxide, silicon oxide, titanium dioxide, silicon nitride, zinc selenide, magnesium fluoride, silicon, hafnium dioxide, and zirconium dioxide.

6. The laser diode with highly reflective layer of claim 4, wherein the material of said metal layer is selected from the group consisting of aluminum, copper, silver, and gold.

7. The laser diode with highly reflective layer of claim 4, wherein the material of said protection layer is selected from the group consisting of aluminum oxide, tantalum pentoxide, silicon dioxide, silicon oxide, titanium dioxide, silicon nitride, zinc selenide, magnesium fluoride, silicon, hafnium dioxide, and zirconium dioxide.

8. The laser diode with highly reflective layer of claim 4, wherein the thickness of said insulation layer is between 200 Å and 3000 Å.

9. The laser diode with highly reflective layer of claim 4, wherein the thickness of said protection layer is between 200 Å and 3000 Å.

10. The laser diode with highly reflective layer of claim 4, wherein the thickness of the metal layer is equal to or greater than 100 Å.
